(19) United States
(12) Patent Application Publication
(10) Pub. No.: US 2012/0319171 A1
(43) Pub. Date: Dec. 20, 2012

(54) SEMICONDUCTOR WAFER, SEMICONDUCTOR DEVICE, AND A METHOD OF PRODUCING A SEMICONDUCTOR WAFER

(75) Inventors: Tomoyuki TAKADA, Ibaraki (JP); Sadanori YAMANAKA, Chiba (JP)

(73) Assignee: SUMITOMO CHEMICAL COMPANY, LIMITED, Tokyo (JP)

(21) Appl. No.: 13/594,389

(22) Filed: Aug. 24, 2012

Related U.S. Application Data
(63) Continuation-in-part of application No. PCT/JP2011/001014, filed on Feb. 23, 2011.

(30) Foreign Application Priority Data
Feb. 26, 2010 (JP) 2010-043507

(51) Int. Cl. H01L 29/26; H01L 21/20

(52) U.S. Cl. 257/200; 438/478; 257/E21.09; 257/E29.079

(57) ABSTRACT

A semiconductor wafer includes a base wafer, a first crystal layer, a second crystal layer and a third crystal layer. The first crystal layer has a first surface having a same orientation as the base wafer, and a second surface having a different orientation from the first surface, the second crystal layer has a third surface having the same orientation as the first surface, and a fourth surface having the same orientation as the second surface, the third crystal layer is in contact with a part of the third surface and the fourth surface. A thickness ratio of the second crystal layer in a region adjoining the first surface to a region adjoining the second surface is larger than a thickness ratio of the third crystal layer in a region adjoining the third surface to a region adjoining the fourth surface.

### TECHNICAL FIELD

The present invention relates to a semiconductor wafer, a semiconductor device and a method of producing a semiconductor wafer. The contents of the following Japanese patent application and PCT patent application are incorporated herein by reference:

JP2010-043507 filed on Feb. 26, 2010, and

PCT/JP2011/001014 filed on Feb. 23, 2011.

### BACKGROUND ART

Compared with a semiconductor made of silicon alone, compound semiconductors such as Group 2-6 compound semiconductors, Group 3-5 compound semiconductors and Group 4-4 compound semiconductors have higher breakdown voltages and better high-frequency characteristics, and various electric devices with extensive functions have been developed using such compound semiconductors. A GaAs bulk wafer is used as a wafer on which crystals of such compound semiconductors are grown. However, GaAs bulk wafers are expensive and their heat dissipation capability is not high. Instead, Si wafers are considered to be used to manufacture electronic devices since they are reasonable cost and have a better heat dissipation characteristic.

Patent Document 1 discloses that a Ge layer which is lattice-matched with a compound semiconductor can be provided as an interlayer when an electronic device using the above-mentioned compound semiconductor is fabricated on a Si wafer, resulting in a fine crystal thin film. Non-patent Document 1 discloses that crystallinity of a Ge crystal thin film used as the interlayer can be improved by annealing the Ge crystal thin film which is epitaxially grown on the Si wafer (a base wafer). For instance, Non-patent Document 1 describes that a Ge crystal thin film that is selectively grown at a temperature in the range of from 800° C. to 900° C. is annealed to obtain a Ge crystal thin film with an average dislocation density of 2.3×10⁶ cm⁻². Here, the average dislocation density is one example of a lattice defect density. The above-mentioned Patent Document 1 is JP-A-61-094318, and Non-patent Document is Hsin-Chiao Luan et al. “High-quality Ge epilayers on Si with low threading-dislocation densities,” Appl. Phys. Lett. vol. 75, page 2909, 1999.

### SUMMARY OF THE INVENTION

### Problem to be Solved by the Invention

However, when a Ge crystal is grown as an interlayer on a Si wafer and a crystal of a compound semiconductor is grown on the Ge crystal, Ge atoms can be diffused in a half-grown compound semiconductor during the crystal growth of the compound semiconductor. Moreover, during a heat treatment of the wafer performed before the crystal growth of the compound semiconductor, Ge atoms can be vaporized from the Ge crystal, and the vaporized Ge atoms can be incorporated in the half-grown compound semiconductor. Ge atoms in the compound semiconductor act as a donor and they can reduce the resistance of the compound semiconductor. Therefore, if Ge atoms are diffused in the compound semiconductor, it is difficult to obtain, by crystal growth, a high-resistance semiconductor which is required for device production.

In order to address this drawback, a buffer layer can be formed between the Ge crystal and the compound semiconductor (for example, GaAs) to prevent Ge atoms from diffusing into the compound semiconductor. However, when the Ge crystal is selectively grown, an angled facet is formed in the Ge crystal, and when a crystal growth rate at the angled facet of the Ge crystal (a plane which is not parallel to a surface of the Si wafer) is smaller than a crystal growth rate at a horizontal facet of the Ge crystal (a plane which is parallel to the surface of the Si wafer), a thickness of the buffer layer on the angled facet tends to be smaller than a thickness of the buffer layer on the horizontal facet.

When the buffer layer on the angled facet is not formed thick enough, the buffer layer cannot sufficiently suppress Ge atom diffusion from the Ge crystal on the angled facet into the compound semiconductor. However, when the buffer layer on the angled facet is made thick enough by increasing a growth time for the buffer layer, an area of a mesa-shaped buffer layer on the horizontal facet becomes small, resulting in a small area where a compound semiconductor is to be formed.

### Means for Solving Problem

For a solution to the above-mentioned problems, according to the first aspect related to the present invention, provided is a semiconductor wafer. The semiconductor wafer includes a base wafer, a first crystal layer formed on the base wafer, a second crystal layer that covers the first crystal layer, and a third crystal layer that is formed so as to be in contact with the second crystal layer. The first crystal layer has a first crystal surface that has the same orientation as a surface in which the base wafer is in contact with the first crystal layer, and a second crystal surface that has a different orientation from the first crystal surface, the second crystal layer has a third crystal surface that has the same orientation as the first crystal surface, and a fourth crystal surface that has the same orientation as the second crystal surface, the third crystal layer is in contact with at least a part of each of the third crystal surface and a part of the fourth crystal surface, a thickness ratio of the second crystal layer in a region being in contact with the first crystal surface to the second crystal layer in a region being in contact with the second crystal surface is larger than a thickness ratio of the third crystal layer in a region being in contact with the third crystal surface to the third crystal layer in a region being in contact with the fourth crystal surface.

The semiconductor wafer may have an inhibitor that is formed on the base wafer and has an opening that reaches to the base wafer. The inhibitor inhibits crystal growth of the first crystal layer, and the first crystal layer is formed inside the opening. For instance, the first crystal layer has a composition of CₓSi_{y}Ge_{z}Sn_{1-x-y-z} (0≦x<1, 0≦y<1, 0<z≦1, and 0<x+y+z≦1). For example, the third crystal layer is a Group 3-5 compound semiconductor containing an As atom. For instance, the second crystal layer has a composition of AlₐGa_{b}In_{c}As_{d}Pₑ (0≦a<1, 0≦b<1, 0<c≦1, a+b+c=1, 0≦d<1, 0<e≦1, and d+e=1), and the third crystal layer has a composition of Al_{f}Ga_{g}InₕAsᵢPⱼ (0≦f≦1, 0≦g≦1, 0≦h<1, f+g+h=1, 0<i≦1, 0≦j<1, and i+j=1).

The semiconductor wafer may further include a fourth crystal layer formed on the third crystal layer, and the fourth crystal layer includes at least two layers selected from the group consisting of a GaAs layer, an AlGaAs layer, an InGaAs layer, an InGaP layer and an AlInGaP layer. The semiconductor wafer may include more than one laminate of the second crystal layer and the third crystal layer that is stacked on the first crystal layer in a stacking direction of the second crystal layer and the third crystal layer.

According to the second aspect related to the invention, provided is a semiconductor device that includes the above-stated semiconductor wafer and a semiconductor element formed in the fourth crystal layer.

According to the third aspect related to the invention, provided is a method of producing a semiconductor wafer. The method includes forming a first crystal layer on a base wafer, epitaxially growing a second crystal layer that covers the first crystal layer, and epitaxially growing a third crystal layer that is in contact with the second crystal layer. Here, the first crystal layer has a first crystal surface that has the same orientation as a surface in which the base wafer is in contact with the first crystal layer, and a second crystal surface that has a different orientation from the first crystal surface, and the second crystal layer has a third crystal surface that has the same orientation as the first crystal surface, and a fourth crystal surface that has the same orientation as the second crystal surface. In the epitaxially growing the second crystal layer and in the epitaxially growing the third crystal layer, the third crystal layer is epitaxially grown such that it is in contact with at least a part of the third crystal surface and a part of the fourth crystal surface, and a growth rate ratio of the second crystal layer at the first crystal surface to the second crystal layer at the second crystal surface is larger than a growth rate ratio of the third crystal layer at the third crystal surface to the third crystal layer at the fourth crystal surface. In the forming a first crystal layer, the first crystal layer may be annealed at a temperature in the range of from 700° C. to 950° C.

### BRIEF DESCRIPTION OF THE DRAWINGS

FIG. 1A is a sectional view of a part of a semiconductor wafer 100.

FIG. 1B is an enlarged sectional view of a portion B in FIG. 1A.

FIG. 2A is a sectional view of a part of the semiconductor wafer 100 during a manufacturing process.

FIG. 2B is a sectional view of the part of the semiconductor wafer 100 during a manufacturing process.

FIG. 3 is a sectional view of a part of a semiconductor device 200.

FIG. 4 is a sectional view of a part of a semiconductor device 300.

FIG. 5A shows SIMS data indicating an impurity depth profile of the semiconductor wafer in Example 1.

FIG. 5B shows SIMS data indicating an impurity depth profile of the semiconductor wafer in Comparative Example 1.

FIG. 6 illustrates a cross-sectional shape of the semiconductor wafer in Example 1.

FIG. 7 illustrates a cross-sectional shape of a semiconductor wafer in Example 2.

### MODE FOR CARRYING OUT THE INVENTION

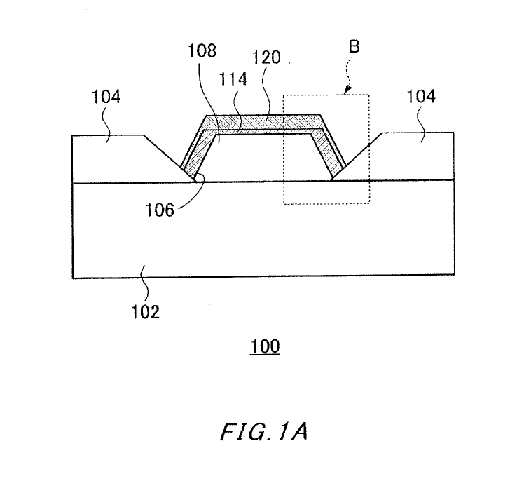

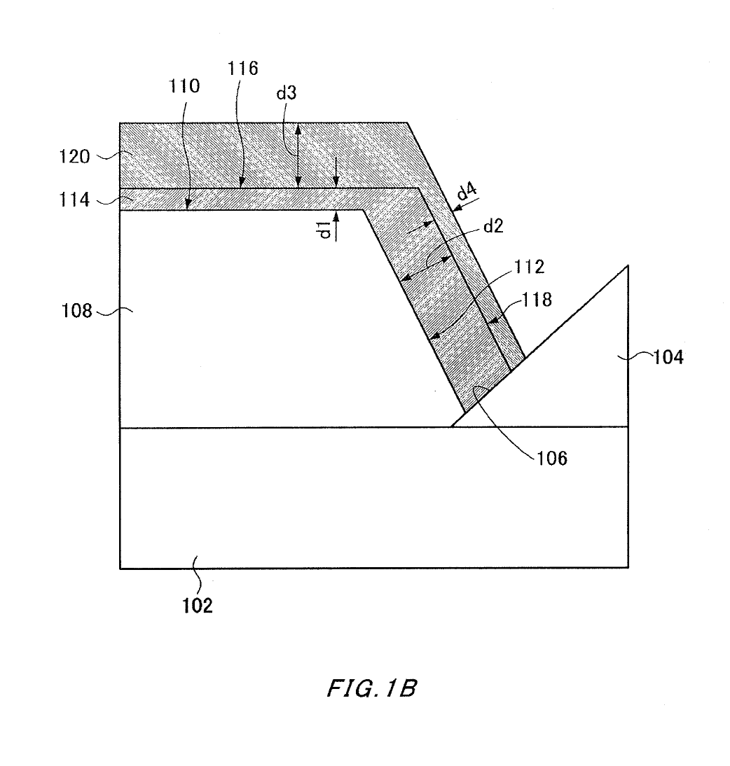

The present invention will be hereunder described with reference to illustrative embodiments. FIG. 1A is a sectional view of a part of a semiconductor wafer 100, and FIG. 1B is an enlarged sectional view of the portion B in FIG. 1A. The semiconductor wafer 100 includes a base wafer 102, an inhibitor 104, a first crystal layer 108, a second crystal layer 114, and a third crystal layer 120. A surface of the base wafer 102 includes silicon. For example, the base wafer 102 is a Si wafer or an SOI wafer. As the base wafer, a wafer whose surface is made of silicon with the main plane (100) or an off cut angle wafer having a growth surface disposed slightly away from the plane (100) can be used.

The inhibitor 104 inhibits crystal growth of the first crystal layer 108. The inhibitor 104 is made of, for example, silicon oxide, silicon nitride, or silicon oxynitride. The inhibitor 104 is formed on the base wafer 102. An opening 106 that reaches to the base wafer 102 is formed in the inhibitor 104.

The first crystal layer 108 is formed inside the opening 106 and on the base wafer 102. The first crystal layer 108 is lattice-matched or pseudo-lattice-matched to silicon existing on a surface of the base wafer 102. The second crystal layer 114 is formed on the first crystal layer 108 so as to cover the first crystal layer 108. In other words, the second crystal layer 114 is in contact with all the surfaces of the first crystal layer 108 except for the surface that adjoins the base wafer 102. The third crystal layer 120 is formed in contact with the second crystal layer 114.

The first crystal layer 108 has a first crystal surface 110 and a second crystal surface 112. For instance, the orientation of the first crystal surface 110 is same as the orientation of the surface of the base wafer 102. The first crystal surface 110 may be parallel to the surface of the base wafer 102. The second crystal surface 112 has a different orientation from the orientation of the first crystal surface 110. The second crystal surface 112 is not parallel to the surface of the base wafer 102.

The area of the first crystal surface 110 is smaller than the area of a region of the first crystal layer 108 where it adjoins the base wafer 102. The first crystal layer 108 has, for example, more than one second crystal surface 112 that has a different orientation each other. When the region of the first crystal layer 108 that is in contact with the base wafer 102 has a rectangular shape, the first crystal layer 108 has four second crystal surfaces 112 that adjoin four sides of the first crystal surface 110 and four sides of the region where it adjoins the base wafer 102.

The second crystal layer 114 has a third crystal surface 116 and a fourth crystal surface 118. The third crystal surface 116 has a different orientation from the orientation of the fourth crystal surface 118. The orientation of the third crystal surface 116 is same as the orientation of the first crystal surface 110. The orientation of the fourth crystal surface 118 is same as the orientation of the second crystal surface 112. The third crystal layer 120 is in contact with at least a part of the third crystal surface 116 and the fourth crystal surface 118 of the second crystal layer 114.

The second crystal layer 114 covers the first crystal layer 108. The third crystal surface 116 that corresponds to the first crystal surface 110 and the fourth crystal surface 118 that corresponds to the second crystal surface 112 are formed on the surface of the second crystal layer 114. The second crystal layer 114 has a plurality of the fourth crystal surfaces 118 that correspond to the each of the second crystal surfaces 112.

A thickness ratio of the second crystal layer 114 in the region where it is in contact with the second crystal surface 112 to the second crystal layer 114 in the region where it is in contact with the first crystal surface 110 is larger than a thickness ratio of the third crystal layer 120 in the region where it is in contact with the fourth crystal surface 118 to the third crystal layer 120 in the region it is in contact with the third crystal surface 116. Here, a thickness of a crystal layer refers to the distance between a first surface and a second surface of the crystal layer in a direction perpendicular to the second surface, where the first surface and the second surface oppose each other. The semiconductor wafer 100 may further include other layers between the third crystal layer 120 and the fourth crystal surface 118. In this case, the thickness of the third crystal layer 120 is a thickness of the third crystal layer 120 in the region where it adjoins the other layer.

When the second crystal layer 114 is epitaxially grown on the first crystal layer 108, a growth rate ratio of the second crystal layer 114 on the first crystal surface 110 to the second crystal layer 114 on the second crystal surface 112 is larger than a growth rate ratio of the third crystal layer 120 on the fourth crystal surface 118 to the third crystal layer 120 on the third crystal surface 116 when the third crystal layer 120 is epitaxially grown on the second crystal layer 114.

In other words, if a growth time of an epitaxial growth is same, different growth rates result in different thicknesses of epitaxially-grown layers. When a thickness of the second crystal layer 114 in the region that is in contact with the first crystal surface 110 is denoted as d1, a thickness of the second crystal layer 114 in the region that is in contact with the second crystal surface 112 is denoted as d2, a thickness of the third crystal layer 120 in the region that is in contact with the third crystal surface 116 is denoted as d3, and a thickness of the third crystal layer 120 in the region that is in contact with the fourth crystal surface 118 is denoted as d4, the relationship (d2/d1)>(d4/d3) is satisfied. When the thicknesses d1, d2, d3 and d4 satisfy the above relationship, it is possible to prevent atoms contained in the first crystal layer 108 from diffusing inside the compound semiconductor formed on the third crystal layer 120.

The first crystal layer 108 is, for example, CₓSi_{y}Ge_{z}Sn_{1-x-y-z} (0≦x<1, 0≦y<1, 0<z≦1, and 0<x+y+z≦1). The first crystal layer 108 is preferably Si_{y}Ge_{z} (0≦y<1 and 0<z≦1), more preferably Ge. The first crystal layer 108 can be formed by, for example, selective epitaxial growth using the inhibitor 104 as a mask. As the epitaxial growth, a chemical vapor deposition method (hereinafter may be referred to as CVD), a metal organic chemical vapor deposition method (hereinafter may be referred to as MOCVD), or a molecular beam epitaxy method (hereinafter may be referred to as MBE) can be used. It is preferable that the first crystal layer 108 be annealed at a temperature and for a duration with which lattice defects can reach to, for example, the second crystal surface 112. When the lattice defects reach to the second crystal surface 112, the crystallinity of the first crystal layer 108 can be enhanced.

The second crystal layer 114 is, for example, AlₐGa_{b}In_{c}As_{d}Pₑ (0≦a<1, 0≦b<1, 0≦c<1, a+b+c=1, 0≦d<1, 0≦e<1, and d+e=1). The second crystal layer 114 is preferably lattice-matched or pseudo-lattice-matched to the first crystal layer 108. When the second crystal layer 114 includes a P atom as a Group 5 element, the second crystal layer 114 tends to grow on an angled facet (the second crystal surface 112) formed on the first crystal layer 108. Since the second crystal layer 114 tends to grow on the second crystal layer 112, the thickness of the second crystal layer 114 in the region that is in contact with the first crystal surface 110 can be kept small, while the thickness of the second crystal layer 114 in the region that is in contact with the second crystal surface 112 can be made to a desired thickness at which it suppresses the diffusion or evaporation of Ge atoms contained in the first crystal layer 108 through the second crystal surface 112.

The second crystal layer 114 may be formed in contact with the first crystal layer 108 or may be formed with an interlayer interposed therebetween. The interlayer is, for example, a buffer layer grown at a low temperature. By using the low-temperature grown buffer layer as the interlayer, it is possible to prevent the first crystal layer 108 from being decomposed and reacted with a source gas. A growth temperature for the low-temperature grown buffer layer is preferably equal to or less than 600° C.

The third crystal layer 120 is, for example, a Group 3-5 compound semiconductor that contains an As atom. More specifically, the third crystal layer 120 is, for example, Al_{f}Ga_{g}InₕAsᵢPⱼ (0≦f≦1, 0≦g≦1, 0≦h<1, f+g+h=1, 0<i≦1, 0≦j<1, and i+j=1). It is preferable that the difference in lattice constant between the third crystal layer 120 and GaAs be smaller than the difference in lattice constant between the second crystal layer 114 and GaAs. The third crystal layer 120 can be easily lattice-matched to GaAs so that the third crystal layer 120 can be appropriately used for crystal growth of GaAs thereon. However, the group 3-5 compound semiconductor contains As atoms and therefore it is difficult to be formed on the angled facet (the fourth crystal surface 118). On the other hand, the second crystal layer 114 is formed between the fourth crystal surface 118 and the first crystal surface 110 so that it is possible to suppress evaporation or diffusion of Ge atoms included in the first crystal layer 108.

Values for d, e, i and j in the compositions of the second crystal layer 114 and the third crystal layer 120 are preferably set as follows: d=0, e=1, i=1, and j=0. In other words, AlₐGa_{b}In_{c}P is preferred as the second crystal layer 114, and Al_{f}Ga_{g}InₕAs is preferred as the third crystal layer 120.

It is preferable that the thickness of the second crystal layer 114 be in a range from 1 nm to 500 nm. It is preferable that the thickness of the third crystal layer 120 be in a range from 1 nm to 500 nm. By setting the thickness of the second crystal layer 114 or the third crystal layer 120 to 1 nm or more, the angled facet (the second crystal surface 112) of the first crystal layer 108 can be covered with the crystal layer that is thick enough to suppress the evaporation and diffusion of Ge atoms. Moreover, by setting the film thickness of the second crystal layer 114 or the third crystal layer 120 to 500 nm or less, it is possible to reduce the entire film thickness of the stack including the second crystal layer 114 and the third crystal layer 120, resulting in reduced cost of raw materials. Furthermore, it is possible to prevent defects during a resist applying step or an exposure step in the device producing process, and the defects are caused when the film stack is too thick.

With the angled facet (the second crystal surface 112) formed on the first crystal layer 108, the area of the face parallel to the main plane of the first crystal layer 108 becomes smaller compared to the bottom area of the opening 106. Accordingly, when the total thickness of the stack including the second crystal layer 114 and the third crystal layer 120 becomes large, the area of the surface parallel to the main plane becomes further smaller and only the small area will be left for the device fabrication. In consideration of this fact, the thickness of the second crystal layer 114 and the third crystal layer 120 is respectively set to 500 nm or less, more preferably set to 100 nm or less, and in this way the area of the surface parallel to the main plane of the base wafer 102 will not be reduced.

The second crystal layer 114 tends to grow on the angled facet (the second crystal surface 112) of the first crystal layer 108, and when the thickness of the second crystal layer is too thick, the angled facet portion protrudes from the surface (the third crystal surface 116) parallel to the main plane of the base wafer 102 and it disturbs the profile of the second crystal layer 114. By setting the thickness of the second crystal layer 114 to 500 nm or less, more preferably to 100 nm or less, it is possible to prevent the profile of the second crystal layer 114 from being undesirably changed.

The third crystal layer 120 contains As as a Group 5 element, and it tends to grow on the surface (the third crystal surface 116) parallel to the main plane of the base wafer 102. Thus, the surface parallel to the main plain of the base wafer 102, which is required for growth of a functional layer a device active region, can be grown evenly so that differences in thickness of the second crystal layer 114 can be compensated. For instance, by setting the film thickness of the third crystal layer 120 to 1 nm or more, the thickness differences of the second crystal layer 114 can be compensated, and consequently the third crystal layer 120 can have a smooth surface.

Moreover, by setting the film thickness of the third crystal layer 120 to 500 nm or less, more preferably to 100 nm or less, it is possible to limit the total thickness of the second crystal layer 114 and the third crystal layer 120 combined, and as a result, the area of the surface parallel to the main plane of the base wafer 102, which is necessary for the functional layer to be grown, will not be reduced. Here, the film thicknesses of the second crystal layer 114 and the third crystal layer 120 can be adjusted and optimized according to the size of the opening 106 and the size of the fabricating device.

When a Ge layer is formed as the first crystal layer 108 inside the opening 106 of the inhibitor 104, crystal defects such as crystal dislocation is likely to occur in the Ge crystal since the lattice constant and property values are different between a Si crystal and the Ge crystal. Here, when the opening 106 is made small and the plane area of the Ge layer formed therein is made small, effects of the difference in the lattice constant and thermal expansion coefficient are mitigated and it reduces the chances of dislocation. Even when annealing is performed after the Ge formation, dislocation would less occur when the plane area of the Ge layer is smaller.

Considering this fact, it is preferable to set the base area of the opening 106 to 1 mm² or less. More preferably, the base area of the opening 106 is set in a range from 25 μm² to 2500 μm². If the base area of the opening 106 is smaller than 25 μm², the area for an electronic element or a photonic element to be fabricated becomes too small. The second crystal layer 114 or the third crystal layer 120 may be formed on the inhibitor 104. Note that the semiconductor wafer 100 does not necessarily have the inhibitor 104 and the opening 106.

When the first crystal layer 108, the second crystal layer 114 and the third crystal layer 120 are sequentially grown on the base wafer 102 by CVD and a Si wafer is used as the base wafer 102, an off cut angle wafer which has a growth plane disposed slightly away from the plane (100) of Si can be used. The off cut angle wafer is preferably used since chances of anti-phase domains generation will be reduced.

However, when the off cut angle wafer is used as the base wafer 102, and only one second crystal layer 114 and one third crystal layer 120 are deposited, amounts of rises of edges in the second crystal layer 114 which is thickly formed will differ depending on directions, and it could adversely affect the device process after the device structure is deposited. When the second crystal layer 114 and the third crystal layer 120 are repeatedly deposited to form a multi-layer, the rise of the edges can be prevented.

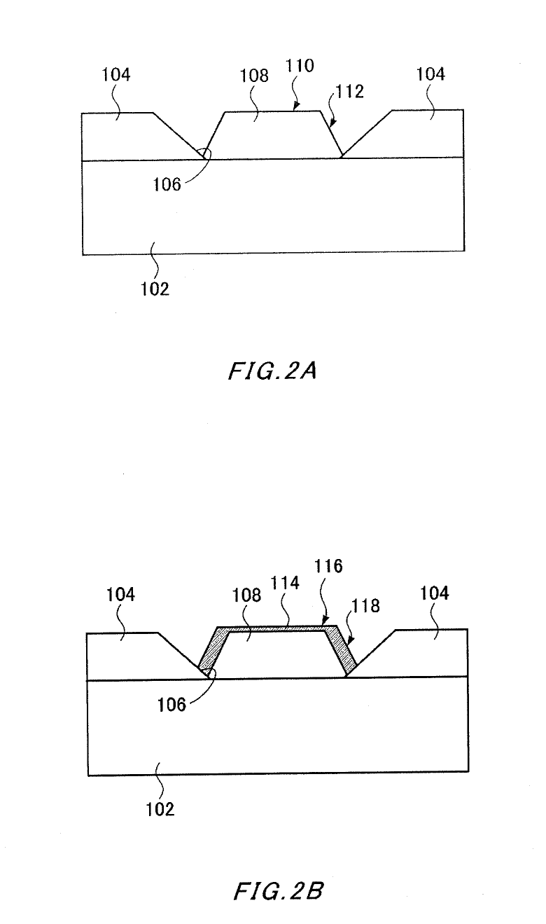

A method of producing the semiconductor wafer 100 will be now described. FIG. 2A and FIG. 2B show sectional views of a part of the semiconductor wafer 100 during a manufacturing process of the semiconductor wafer 100.

Referring to FIG. 2A, the inhibitor 104 is formed on the base wafer 102, and then the opening 106 that reaches to the base wafer 102 is formed in the inhibitor 104. Subsequently the first crystal layer 108 is formed in the opening 106 and on the base wafer 102. Referring next to FIG. 2B, the second crystal layer 114 is epitaxially grown such that it covers the first crystal layer 108. Subsequently the third crystal layer 120 is epitaxially grown such that it is in contact with the second crystal layer 114, and the semiconductor wafer 100 illustrated in FIG. 1A is obtained.

Here, in the step of growing the second crystal layer 114 and the third crystal layer 120, an epitaxial growth condition is set such that the growth rate ratio of the second crystal layer 114 on the first crystal surface 110 to the second crystal layer 114 on the second crystal surface 112 is larger than the growth rate ratio of the third crystal layer 120 on the fourth crystal surface 118 to the third crystal layer 120 on the third crystal surface 116.

In the step of growing the Ge layer as the first crystal layer 108, a chemical vapor deposition method using GeH₄ as a source gas can be used. The first crystal layer 108 is then annealed to reduce crystal defects. For example, the first crystal layer 108 can be annealed in the same vapor deposition apparatus in which the first crystal layer 108 has been epitaxially grown without taking out the wafer from the apparatus.

The first crystal layer 108 is preferably annealed at the temperature and for duration with which crystal defects therein can reach to, for example, the second crystal surface 112. The temperature and the time duration for the annealing are optimized depending on the size of the first crystal layer 108. When the first crystal layer 108 is a Ge layer, an appropriate annealing temperature is any temperature in a range from 700° C. to 950° C. When the annealing temperature is lower than 700° C., crystal defects do not sufficiently travel and it takes a long time to reduce dislocations. Whereas when the annealing temperature is above 950° C., the first crystal layer 108 tends to be decomposed or vaporized undesirably.

The annealing temperature to anneal the first crystal layer 108 is set to more preferably in a range from 750° C. to 900° C. By annealing the first crystal layer 108 at a temperature in the range of from 750° C. to 900° C., dislocations in the crystal can be reduced and the undesirable profile change of the first crystal layer 108 can be prevented. The dislocation can also be reduced by cycle annealing in which temperature is repeatedly changed.

A wafer holder with a resistance heating or a high-frequency induction heating can be used as a heat source for annealing. Alternatively, a lamp heating by infrared irradiation can also be adopted. When the cycle annealing is performed, the lamp heating can be adopted to reduce the cycle of annealing.

MOCVD or MBE can be used to epitaxially grow the second crystal layer 114 and the third crystal layer 120. When the second crystal layer 114 is formed by MOCVD, PH₃ is used as one of the materials. By using PH₃ as at least one of the materials, it is possible to form the second crystal layer 114 containing a P atom on the first crystal layer 108, and therefore a fine hetero-interface can be obtained without decomposition of the Ge layer included in the first crystal layer 108.

AsH₃ is used as at least one of the materials to form the third crystal layer 120. By using AsH₃ as at least one of the materials, it is possible to form the third crystal layer 120 containing As on the second crystal layer 114, and therefore a fine crystal with less impurity contained therein can be obtained. The growth temperature of the second crystal layer 114 and the third crystal layer 120 is preferably set to a temperature in a range of from 450° C. to 700° C. When the growth temperature of the second crystal layer 114 and the third crystal layer 120 is lower than 450° C., a fine crystal quality cannot be obtained, and whereas when the growth temperature is above 700° C., Ge atoms contained in the first crystal layer 108 tend to be undesirably incorporated into the compound semiconductor formed above the third crystal layer 120.

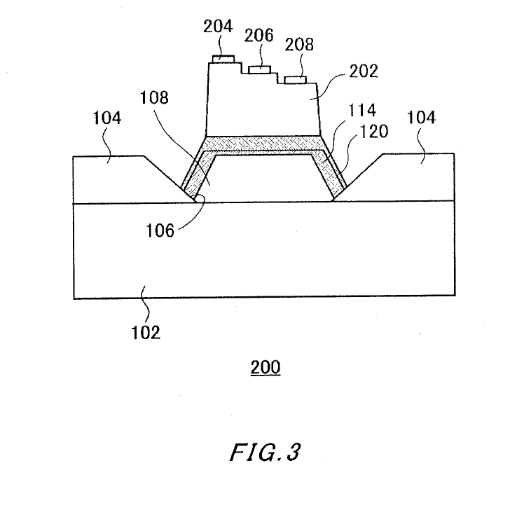

FIG. 3 is a sectional view of a part of a semiconductor device 200. The semiconductor device 200 includes a fourth crystal layer 202 formed on the third crystal layer 120 of the semiconductor wafer 100. As the fourth crystal layer 202, at least two layers selected from the group consisting of a GaAs layer, an AlGaAs layer, an InGaAs layer, an InGaP layer and an AlInGaP layer can be formed. It is preferable that the fourth crystal layer 202 include at least one semiconductor layer with a carrier concentration of 1×10¹⁷ cm⁻³ or less. It is also preferable that the fourth crystal layer 202 include at least one semiconductor layer with a Ge atom concentration of 1×10¹⁷ cm⁻³ or less.

By processing the fourth crystal layer 202, a desired semiconductor device can be formed. The semiconductor device is, for example, an electronic element or a photonic element. The electronic element is, for example, an HBT. The photonic element is, for example, a light emitting element or a light receiving element. Photonic elements and electronic elements can be mixed to form the semiconductor device. FIG. 3 illustrates a hetero-junction-bipolar transistor (HBT). On the fourth crystal layer 202, an emitter electrode 204, a base electrode 206, and a collector electrode 208 of the HBT are formed.

It is preferable that the fourth crystal layer 202 include a multi-layered structure made of a GaAs crystal which is lattice-matched or pseudo-lattice-matched to a GaAs crystal. When the first crystal layer 108 is a Ge layer, Ge crystals in the Ge layer are pseudo-lattice-matched to GeAs crystals in the fourth crystal layer 202. Because dislocation will not occur in the layer which is lattice-matched or pseudo-lattice-matched to the GaAs crystal, it is possible to grow the fourth crystal layer 202 with a fine quality. When the thickness of the layer forming the fourth crystal layer 202 is small, it is possible to grow a fine-quality crystal without dislocation even when there is a difference in the lattice constant.

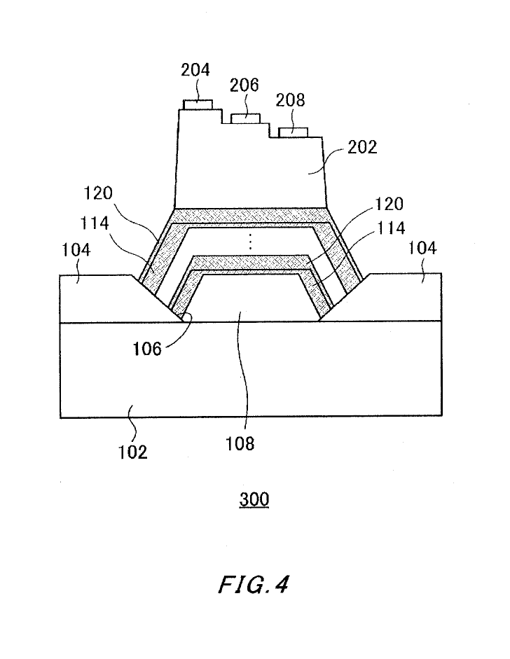

FIG. 4 is a sectional view of a part of a semiconductor device 300. In the semiconductor device 300, the second crystal layer 114 is formed such that it is in contact with the first crystal layer 108, and the third crystal layer 120 is formed such that it adjoins the second crystal layer 114. Moreover, a plurality of laminates of the second crystal layer 114 and the third crystal layer 120 are formed to provide a stack.

The fourth crystal layer 202 is formed on the third crystal layer 120 that is disposed furthest from the base wafer 102, and an HBT is formed in the fourth crystal layer 202. Since the semiconductor device 300 includes the stack of the second crystal layers 114 and the third crystal layers 120, the effect of preventing Ge evaporation or diffusion can be enhanced. Three or more than three laminates of the second crystal layer 114 and the third crystal layer 120 are preferably provided, more preferably, five or more than five laminates are provided.

The stack of the second crystal layer 114 and the third crystal layer 120 is, for example, formed as the first crystal layer 108/the second crystal layer 114/the third crystal layer 120 in this order. More than one laminate of the second crystal layer 114 and the third crystal layer 120 is further formed, and the furthest surface of the stack from the base wafer 102 is a laminate of the second crystal layer 114/the third crystal layer 120.

Alternatively, the stack can be formed as the first crystal layer 108/the third crystal layer 120/the second crystal layer 114/the third crystal layer 120 in this order, and more than one laminate of the second crystal layer 114 and the third crystal layer 120 is further formed. The furthest surface of the stack from the base wafer 120 may be a set of the second crystal layer 114/the third crystal layer 120. It is preferable that among a plurality of the third crystal layers 120, an area of the third crystal layer 120 that is disposed at the largest distance from the first crystal layer 108 be larger than an area of the third crystal layer 120 that is disposed at the smallest distance from the first crystal layer 108.

In the semiconductor wafer 100 illustrated in FIG. 1A, the semiconductor device 200 illustrated in FIG. 3, and the semiconductor device 300 illustrated in FIG. 4 may have a plurality of the openings 106 in the inhibitor 104, and the first crystal layer 108 may be formed in each of the plurality of openings 106. More than one inhibitor 104 may be formed, and thus a plurality of the openings 106 may be formed in each of the inhibitor 104. When more than one inhibitor 104 is formed, it is preferable that the inhibitors 104 be formed such that distances or directions among adjacent inhibitors 104 are same. For example, a plurality of the inhibitors 104 are arranged in a grid pattern. The plurality of inhibitors 104 may be arranged at regular intervals.

When more than one opening 106 is formed in each of the inhibitors 104, it is preferable that an electronic element or a photonic element is formed in each of the openings 106. Moreover, it is preferable that the openings 106 in the inhibitor 104 be arranged such that distances or directions among adjacent openings 106 are same. For example, a plurality of the openings 106 are preferably arranged in a grid pattern. The plurality of openings 106 may be arranged at regular intervals. By arranging the openings 106 in some regular patterns, the film thickness of the crystal layer which is epitaxially grown can be easily controlled.

It is preferable that the electronic elements and the photonic elements formed in the openings 106 be wired each other. When the same electronic element or photonic element is formed in each of the openings 106, it is preferable that the openings 106 be arranged at regular intervals. For example, an electronic element such as a hetero-junction-bipolar transistor can be formed in each of the openings 106, and the formed electronic elements can be connected each other in parallel to form an electronic device. A photonic device can be formed by connecting photonic elements that each have a light emitting section or a light receiving section and are formed in the openings 106 respectively, or connecting the photonic elements to other electronic elements formed on the base wafer 102.

### EXAMPLES

### Example 1

As the base wafer 102, a commercially available monocrystalline Si wafer that had an off angle of 6° from the plane (100) in the direction of <110> was provided. The inhibitor 104 made of SiO₂ was formed on the surface of the base wafer 102 by a thermal oxidation method. The opening 106 was then formed in the inhibitor 104 by performing patterning using photolithography. Subsequently, a Ge layer that serves as the first crystal layer 108 was selectively grown inside the opening 106 by low-pressure CVD using GeH₄ as a source gas. Annealing was further performed in the CVD chamber to enhance the quality of the Ge crystal.

The base wafer 102 was then removed from the CVD chamber and was set in an MOCVD chamber. Hydrogen was used as a carrier gas, and trimethyl gallium (hereinafter may be referred to as TMG) and arsine were used as the material, and a GaAs buffer layer was grown at a growth temperature of 550° C. Subsequently, the growth temperature was changed to 640° C., and TMG and arsine were used as the material gas to grow a GaAs layer. The thickness of the GaAs layer was 250 nm.

Furthermore, the growth temperature was changed to 610° C., and an In_{0.48}Ga_{0.52}P layer was formed as the second crystal layer 114 using trimethyl indium (hereinafter may be referred to as TMI) TMG and phosphine, and a GaAs layer was formed as the third crystal layer 120 using TMG and arsine. Moreover, a laminate of an In_{0.48}Ga_{0.52}P layer and a GaAs layer was repeatedly formed to obtain a multilayer film including the stack of the second crystal layers and the third crystal layers. The growth thickness of the In_{0.48}Ga_{0.52}P layer was 10 nm, the thickness of the GaAs layer was 20 nm, and ten sets of these layers were provided. Furthermore, a GaAs layer was grown as a part of the fourth crystal layer 202.

### Comparative Example 1

Instead of the multi-layer film of the In_{0.48}Ga_{0.52}P layers and the GaAs layers, a GaAs layer was formed in Comparative Example 1. Rest of the configuration in the semiconductor wafer was same as Example 1.

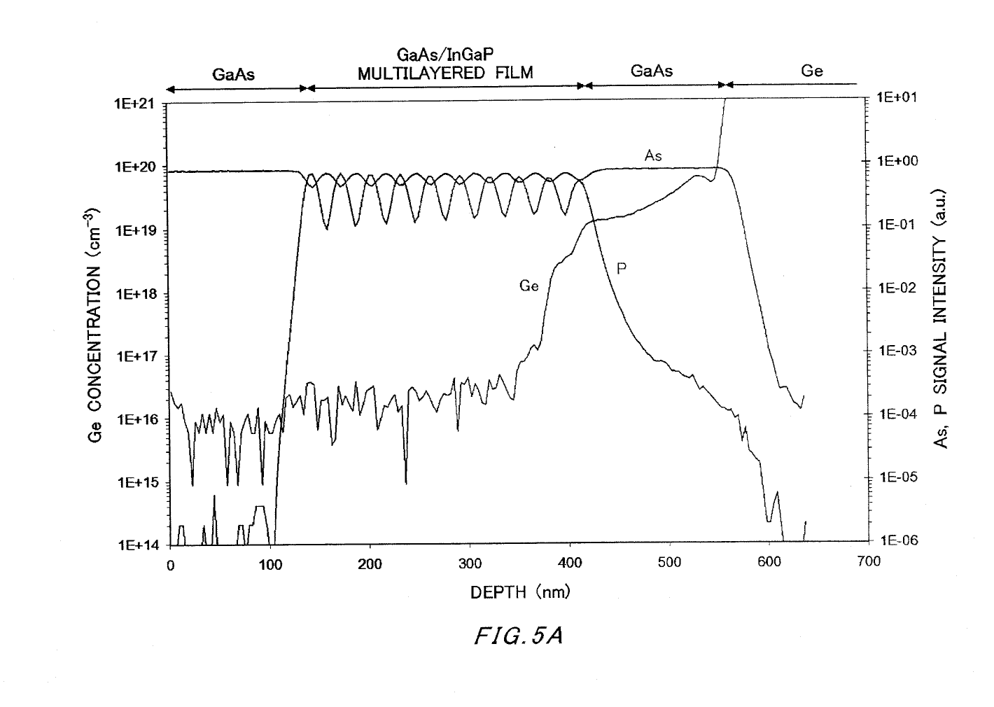

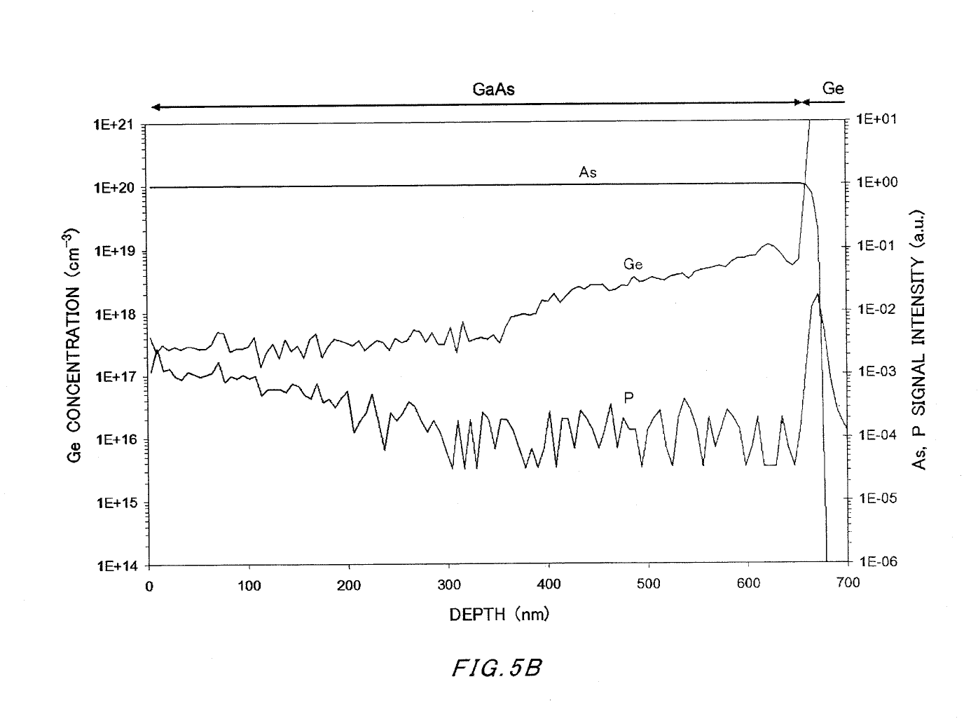

Impurity depth profile (the concentration distribution) in a part of the semiconductor wafer where the inhibitor 104 did not exist was measured for Example 1 and Comparative Example 1 by Secondary Ion Mass Spectrometry (SIMS). FIG. 5A shows SIMS data indicating an impurity depth profile of the semiconductor wafer in a first embodiment, and FIG. 5B shows SIMS data indicating an impurity depth profile of the semiconductor wafer in a comparative example.

Referring to FIG. 5A, the concentration of Ge atoms sharply drops in the multi-layered film of the In_{0.48}Ga_{0.52}P layers and the GaAs layers in Example 1. The Ge concentration of the GaAs layer (a part of the fourth crystal layer 202) at the position in the GaAs layer (a part of the fourth crystal layer 202) 500 nm to 600 nm away from the interface between the Ge layer of the first crystal layer 108 and the GaAs layer (the GaAs buffer layer) was about 1×10¹⁶ m⁻³. Whereas in Comparative Example 1, the Ge concentration of the GaAs crystal in the GaAs layer at the position 500 nm to 600 nm away from the interface between the Ge layer of the first crystal layer 108 and the GaAs layer was about 3×10¹⁷ m⁻³, which was more than ten times of the concentration in Example 1.

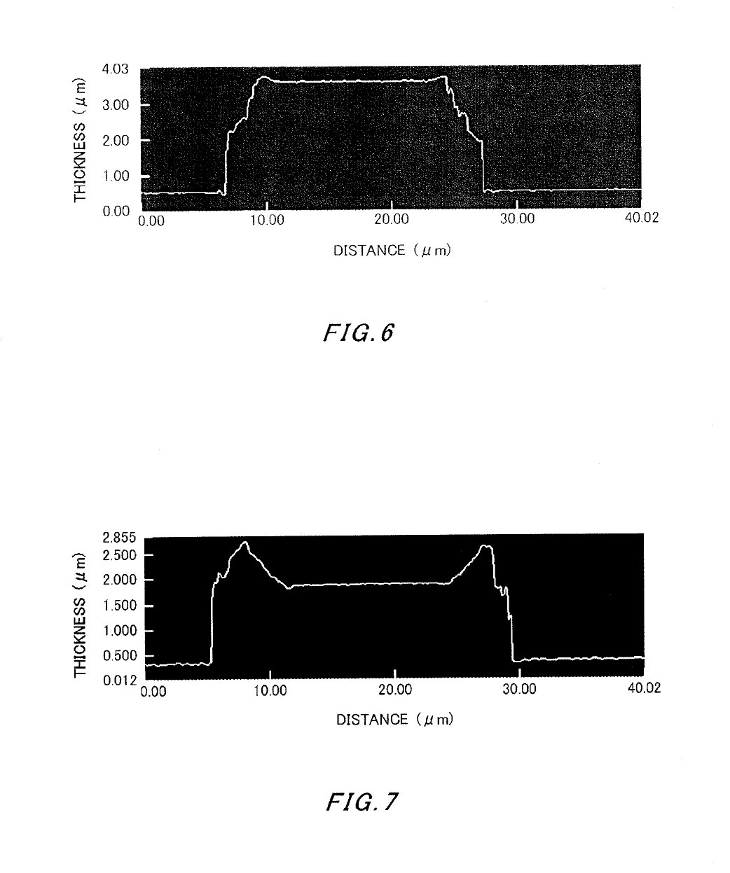

FIG. 6 illustrates a cross-sectional shape of the semiconductor wafer in the first embodiment. The cross-sectional shape shown in FIG. 6 was the section of the semiconductor wafer which was cut vertically and measured by a laser microscope. FIG. 6 shows the sectional view of the multi-layered structure including the Ge layer (the first crystal layer 108), the GeAs buffer layer, the GaAs layer, the 10 laminates of the In_{0.48}Ga_{0.52}P layer (the second layer 114) and the GaAs layer (the third crystal layer 120) stacked thereon, and the GaAs layer (a part of the fourth crystal layer 202), all of which were grown in the opening 106 of the inhibitor 104.

Referring to FIG. 6, the sectional part of the multi-layered structure had a substantially trapezoid shape, and a sectional portion of the legs of the trapezoid corresponded to the angled facet equivalent to the second crystal surface 112 or the fourth crystal surface 118, and the sectional part of the upper base of the trapezoid corresponded to surface of the multi-layered structure equivalent to the first crystal surface 110 or the third crystal surface 116. It can be seen from FIG. 6 that no rises were formed on the multi-layered structure near the angled facet.

### Example 2

In the same manner as Example 1, SiO₂ which served as the inhibitor 104 was formed on a surface of a monocrystalline Si wafer which was the base wafer 102, and the opening 106 was formed in the inhibitor 104 (SiO₂). Subsequently, in the same manner as Example 1, a Ge layer which served as the first crystal layer 108 was selectively grown in the opening 106 and on the base wafer 102 (the monocrystalline Si wafer), and the Ge layer was then annealed to enhance the quality of the Ge crystal. After that, the base wafer 102 was set in the MOCVD chamber, and the GaAs buffer layer and the GaAs layer were grown in the same manner as Example 1.

Subsequently, under the same condition as Example 1, the In_{0.48}Ga_{0.52} layer was formed as the second crystal layer 114, and the GaAs layer was formed as the third crystal layer 120. Unlike Example 1 in which the laminates of the second crystal layer and the third crystal layer were deposited to form the multi-layered structure, a single In_{0.48}Ga_{0.52}P layer (the second crystal layer 114) and a single GaAs layer (the third crystal layer 120) were formed in Example 2. The thicknesses of the In_{0.48}Ga_{0.52}P layer and the GaAs layer were 200 nm respectively. Moreover, a GaAs layer was grown as a part of the fourth crystal layer 202.

Impurity depth profile of the semiconductor wafer fabricated as described above in a part where the inhibitor 104 did not exist was measured in the same manner as Example 1 by the SIMS. As a result of the measurement, it turned out that the Ge atom concentration sharply dropped in the In_{0.48}Ga_{0.52}P layer, and the Ge concentration in the GaAs layer (a part of the fourth crystal layer 202) at the position 500 nm to 600 nm away from the interface between the Ge layer which was the first crystal layer 108 and the GaAs layer (the GaAs buffer layer) was about 1×10¹⁶ cm⁻³. From this, it was demonstrated that the semiconductor wafer of Example 2 has an effect to suppress contamination of Ge atoms into the GaAs layer (the part of the fourth crystal layer 202) in the same way as the semiconductor wafer of Example 1.

FIG. 7 illustrates a cross-sectional shape of a semiconductor wafer in Example 2. The cross-sectional shape shown in FIG. 7 was the section of the semiconductor wafer which was cut vertically and measured by a laser microscope. FIG. 7 shows the sectional view of the multi-layered structure including the Ge layer (the first crystal layer 108), the GeAs buffer layer, the GaAs layer, the In_{0.48}Ga_{0.52}P layer (the second layer 114) and the GaAs layer (the third crystal layer 120), and the GaAs layer (a part of the fourth crystal layer 202), all of which were grown in the opening 106 of the inhibitor 104.

Referring to FIG. 7, the sectional part of the multi-layered structure had a substantially trapezoid shape. A sectional portion of the legs of the trapezoid corresponded to the angled facet equivalent to the second crystal surface 112 or the fourth crystal surface 118, and the sectional part of the upper base of the trapezoid corresponded to surface of the multi-layered structure equivalent to the first crystal surface 110 or the third crystal surface 116. Unlike Example 1, a small rise was found on the surface of the multi-layered structure near the angled facet in Example 2. This means that the multi-layered structure of Example 2 had a comparable suppressive effect on the Ge atom evaporation or diffusion as Example 1, however the flatness of the multi-layered structure of Example 1 was better than that of Example 2.

### Example 3

In the same manner as Example 1, the inhibitor 104 and the opening 106 were formed on a surface of a monocrystalline Si wafer which was the base wafer 102, a Ge layer was selectively grown in the opening 106, and then the Ge layer was annealed to enhance the quality of the Ge layer. Subsequently, in the same manner as Example 1, the GaAs buffer layer, the GaAs layer, and ten laminates of the In_{0.48}Ga_{0.52}P layer (the second crystal layer 114) and the GaAs layer (the third crystal layer 120) were deposited to form a multi-layered film.

On the multi-layered film, an HBT element structure having the fourth crystal layer that included a Si doped n-type GaAs layer, a Si doped n-type InGaP layer, an undoped GaAs layer, a C doped p-type GaAs layer, a Si doped n-type InGaP layer, a Si doped n-type GaAs layer, a Si doped n-type InGaAs layer deposited in the stated order.

The part grown in the opening 106 in the inhibitor 104 of the semiconductor wafer that had the HBT element structure was observed by a laser microscope, and it was confirmed that no rise was formed on the surface of the multi-layered structure near the facet. An electrode was formed on the semiconductor wafer by applying a photolithography process thereon, and the HBT was fabricated. Electric characteristics of the fabricated HBT were measured and it was confirmed that the HBT was operational as a transistor. A current gain of the fabricated HBT was 198.

Although the present invention has been described with reference to embodiments, the technical scope of the invention shall not be limited to the above embodiments. For example, a laterally-grown compound semiconductor layer which is laterally-grown on the inhibitor 104 can be formed using the multi-layered film of the second crystal layer 114 and the third crystal layer 120 as a seed. In this case, by using SiO₂ and SiN which have a high insulation property to form the inhibitor 104, it is possible to reduce a leak current of the element formed in the laterally-grown compound semiconductor layer toward the substrate side and to reduce a floating capacitance, resulting in an enhanced performance of the element.

The operations, procedures, steps, and stages of each process performed by an apparatus and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

1. A semiconductor wafer comprising:
a base wafer;
a first crystal layer formed on the base wafer;
a second crystal layer that covers the first crystal layer; and
a third crystal layer that is formed so as to be in contact with the second crystal layer, wherein
the first crystal layer has a first crystal surface that has the same orientation as a surface in which the base wafer is in contact with the first crystal layer, and a second crystal surface that has a different orientation from the first crystal surface,
the second crystal layer has a third crystal surface that has the same orientation as the first crystal surface, and a fourth crystal surface that has the same orientation as the second crystal surface,
the third crystal layer is in contact with at least a part of each of the third crystal surface and a part of the fourth crystal surface,
a thickness ratio of the second crystal layer in a region being in contact with the first crystal surface to the second crystal layer in a region being in contact with the second crystal surface is larger than a thickness ratio of the third crystal layer in a region being in contact with the third crystal surface to the third crystal layer in a region being in contact with the fourth crystal surface.

2. The semiconductor wafer according to claim 1, further comprising:
an inhibitor that is formed on the base wafer and has an opening that reaches to the base wafer, the inhibitor inhibiting crystal growth of the first crystal layer, wherein
the first crystal layer is formed inside the opening.

3. The semiconductor wafer according to claim 1, wherein
the first crystal layer has a composition of CₓSi_{y}Ge_{z}Sn_{1-x-y-z} (0≦x<1, 0≦y<1, 0<z≦1, and 0<x+y+z≦1).

4. The semiconductor wafer according to claim 1, wherein
the third crystal layer is a Group 3-5 compound semiconductor containing an As atom.

5. The semiconductor wafer according to claim 4, wherein
the second crystal layer has a composition of AlₐGa_{b}In_{c}As_{d}Pₑ (0≦a<1, 0≦b<1, 0<c≦1, a+b+c=1, 0≦d<1, 0<e≦1, and d+e=1), and
the third crystal layer has a composition of Al_{f}Ga_{g}InₕAsᵢPⱼ (0≦f≦1, 0≦g≦1, 0≦h<1, f+g+h=1, 0<i≦1, 0≦j<1, and i+j=1).

6. The semiconductor wafer according to claim 1, wherein
the second crystal layer is lattice-matched or pseudo-lattice-matched to the first crystal layer.

7. The semiconductor wafer according to claim 1, further comprising:
a fourth crystal layer formed on the third crystal layer, wherein
the fourth crystal layer includes at least two layers selected from the group consisting of a GaAs layer, an AlGaAs layer, an InGaAs layer, an InGaP layer and an AlInGaP layer.

8. The semiconductor wafer according to claim 1, wherein
more than one laminate of the second crystal layer and the third crystal layer is stacked on the first crystal layer in a stacking direction of the second crystal layer and the third crystal layer.

9. A semiconductor device, comprising:
the semiconductor wafer according to claim 7, wherein
a semiconductor element is formed in the fourth crystal layer.

10. A method of producing a semiconductor wafer, the method comprising:
forming a first crystal layer on a base wafer;
epitaxially growing a second crystal layer that covers the first crystal layer; and
epitaxially growing a third crystal layer that is in contact with the second crystal layer, wherein
the first crystal layer has a first crystal surface that has the same plane orientation as a surface in which the base wafer is in contact with the first crystal layer, and a second crystal surface that has a different plane orientation from the first crystal surface,
the second crystal layer has a third crystal surface that has the same plane orientation as the first crystal surface, and a fourth crystal surface that has the same plane orientation as the second crystal surface,
wherein in the epitaxially growing the second crystal layer and in the epitaxially growing the third crystal layer, the third crystal layer is epitaxially grown such that it is in contact with at least a part of the third crystal surface and a part of the fourth crystal surface, and a growth rate ratio of the second crystal layer at the first crystal surface to the second crystal layer at the second crystal surface is larger than a growth rate ratio of the third crystal layer at the third crystal surface to the third crystal layer at the fourth crystal surface.

11. The method according to claim 10, of producing a semiconductor wafer, wherein
in the forming a first crystal layer, the first crystal layer is annealed at a temperature in the range of from 700° C. to 950° C.
